(19) United States
(12) Patent Application Publication
(10) Pub. No.: US 2003/0235986 A1
(43) Pub. Date: Dec. 25, 2003

(54) Silicon oxide etching compositions with reduced water content

(76) Inventors: Wolfgang Sievert, Wunstorf (DE); John McFarland, Scottsdale, AZ (US); Michael A. Dodd, Chandler, AZ (US)

Correspondence Address: HONEYWELL INTERNATIONAL, INC, 101 COLUMBIA ROAD, P.O. BOX 2245, MORRISTOWN, NJ, 07962-2245, US

(21) Appl. No.: 10/176,278

(22) Filed: Jun. 20, 2002

(51) Int. Cl. H01L 21/302; H01L 21/461

(52) U.S. Cl. 438/689

(57) ABSTRACT

Silicon oxide etching solutions consisting essentially of the product of at least one bifluoride source compound dissolved in a solvent consisting of about 90% to 100% by weight of at least one carboxylic acid and 0 to about 10% by weight water, wherein the total concentration of bifluoride source compound is between about 1.25 and about 5.0 moles per kilogram of solvent. Methods for selectively removing silicon oxides and metal silicates from metal surfaces are also disclosed.

### FIELD OF THE INVENTION

The present invention relates to etching compositions having reduced water content for the selective removal of silicon oxides from metal surfaces. In particular, the present invention relates to reduced water content solutions of a bifluoride source compound in a carboxylic acid, and methods for providing selective removal of silicon oxides using these solutions.

### BACKGROUND OF THE INVENTION

The circuitry on a semiconductor chip has to connect with other circuits. These may be chips or display devices, transducers or electro-mechanical devices. Each of these situations will require the imposition of circuitry to interface the chip to the external environment. This interface is supplied by bonding pads.

Physically, bonding pads are the squares of metal, typically aluminum, generally 100 to 150 microns square, that are connected to the pins of the semiconductor package with bonding wires. Bonding pads are normally positioned near to the chip edge. Toward the end of the semiconductor fabrication process, passivation coatings are applied to protect the fabricated device. Silicon oxide films are typically deposited, often pyrolytically, using layers of oxides such as oxynitride, silicon dioxide, phosphorus-silicate-glass, boron-phosphorus-silicate-glass, and the like.

Following deposition the silicon oxide must be removed from the bonding pad so that the fabricated device can interconnect with other circuits. An etching composition is typically employed to remove the passivation coating.

Conventional passivation etchants contain ammonium fluoride, acetic acid, water and additional additives such as ethylene glycol or aluminum acetate. Current processes seek to over-etch the bonding pads to ensure complete elimination of the silicon oxide passivating coating. Over-etching with current products results in significant roughing and pitting of the bonding pad surfaces, creating poor contact points to the detriment of device reliability because current products also attack underlying metal surfaces. The products are known to dissolve pads completely, increasing the manufacturing yield loss.

There exists a need for a selective silicon oxide passivation coating etchant that does not attack underlying metal surfaces.

### DETAILED DESCRIPTION OF THE PREFERRED EMBODIMENTS

This need is met by the present invention. It has now been discovered that products containing bifluoride species will etch silicon oxide films without attacking or corroding underlying metals, including aluminum, even with extended exposure when the water content is kept to a minimum. The present invention thus provides an etching composition that can be used to over-etch silicon oxide containing passivating coatings from the metal surfaces of bonding pads without roughing or pitting the surface or dissolving the pad completely.

Therefore, according to one aspect of the present invention, a silicon oxide etching solution is provided consisting essentially of a solution of at least one bifluoride source compound dissolved in a solvent consisting of about 90% to 100% by weight of one or more carboxylic acids and 0 to about 10% by weight of water, wherein the total bifluoride source compound concentration is between about 1.25 and about 5.0 moles per kilogram of solvent. A level of water in the solvent less than or about five percent by weight is preferred, with a water level between about one and about five percent by weight being more preferred.

In addition, for purposes of the present invention, the terms “film,” “coating” and “layer” are used interchangeably, regardless of whether each is applied as a deliberate step in a process of semiconductor fabrication or as a consequence of the performance of a semiconductor fabrication processing step. “Silicon oxides” refer to the various oxides, including silicon dioxides that are formed by various semiconductor layer or coating fabrication processes, including plasma etching and plasma deposition processes.

Among the preferred bifluoride source compounds is ammonium fluoride, with solutions of ammonium fluoride in acetic acid being particularly preferred. These solutions may be prepared by adding acid anhydrides, such as acetic anhydride, to aqueous solutions of ammonium fluoride, so that the acid anhydrides react with the water to dehydrate the solution and form the corresponding carboxylic acids.

The present invention incorporates the discovery that at elevated temperatures, the acid anhydrides will also react with the ammonium fluoride to form undesirable acid amides that slow the silicon oxide etching rates of the inventive compositions. It has further been discovered that acid amide formation can be reduced to levels that do not adversely affect the inventive composition etching rate by maintaining the temperature of the reaction between ammonium fluoride and an acid anhydride below 40° C., and preferably below 30° C. Therefore, according to another aspect of the present invention, a method is provided for the preparation of reduced water content solutions of ammonium fluoride in carboxylic acids essentially free of carboxylic acid amides, by reacting an aqueous solution of ammonium fluoride with an acid anhydride at a temperature below that at which carboxylic acid amide formation occurs, so that the resulting solution of ammonium fluoride in a carboxylic acid is essentially free of carboxylic acid amides.

For purposes of the present invention, a solution essentially free of carboxylic acid amides is defined as a solution in which the level of any carboxylic acid amide present is insufficient to reduce the etching rate of the composition more than five percent. Preferably, the level of carboxylic acid amide should be undetectable. Furthermore, etching compositions that “consist essentially of” at least one bifluoride source compound and at least one carboxylic acid are defined as being limited to compositions that are essentially free of carboxylic acid amides according to the above-recited definition.

The etching compositions of the present invention exhibit high selectivity to silicon oxide coatings, and do not corrode underlaying metal layers, even with extended exposure. The compositions do not attack metal, and do not promote galvanic etching.

The present invention thus provides etching compositions that can be used in semiconductor fabrication to remove by over-etching the silicon oxide passivating coatings that are formed on bonding pad surfaces, without roughing or pitting the pad surfaces or otherwise dissolving the pad. However, this is but one use for the etching compositions of the present invention, which may be used to selectively remove silicon oxides from essentially any metal surface. For example, the etching compositions can also be used to open semiconductor vias for subsequent metal deposition, or to remove silicon oxide deposits from bonding pads that form as a consequence of essentially any semiconductor fabrication process step, including reactive ion etching process steps.

Therefore, according to another aspect of the present invention, a method is provided for selectively removing silicon oxides from metal surfaces by contacting metal surfaces having silicon oxides thereon with an etching composition according to the present invention for a period of time effective to remove at least a portion of the silicon oxides. The methods of the present invention are suitable for use with metal surfaces formed from aluminum, copper, tungsten, tin, titanium, nickel, vanadium, lead and the like. Methods are preferred in which the silicon oxides are essentially completely removed, and methods in which the silicon oxide is removed from a semiconductor bonding pad or to open a via are particularly preferred.

It has further been discovered that the etching compositions of the present invention exhibit high selectivity to metal silicates such as titanium silicates and aluminum silicates that are formed by various plasma etching processes, and do not attack underlying metal layers or organic dielectric coatings, even with extended exposure. Therefore, according to yet another aspect of the present invention, a method is provided for selectively removing metal silicates from metal surfaces by contacting the surfaces with an etching composition according to the present invention for a period of time effective to remove at least a portion of the silicates. Again, methods are preferred in which the metal silicates are essentially completely removed. The metal surfaces include metal surfaces at least partially coated with at least one organic dielectric compound.

The etching compositions of the present invention consist essentially of a solution of at least one bifluoride source compound in one or more carboxylic acids that optionally include up to about 10% by weight water. For purposes of the present invention, carboxylic acids are defined as including mono-, di- and tricarboxylic acids; esters, amides and any unreacted residual anhydrides thereof; as well as amino acids and halogenated carboxylic acids. Monocarboxylic acids are preferred. In addition, carboxylic acid compounds having from zero to five carbon atoms in addition to the carboxylate carbon(s) are preferred, with acetic acid being most preferred. More than one carboxylic acid may be used, but, as is readily understood by those skilled in the art, when an acidic proton is needed to form the biflouride species, at least one carboxylic acid must contain an acidic proton.

The bifluoride source compounds of the present invention form bifluoride species [(HF₂)⁻]when dissolved in the carboxylic acids of the inventive etching compositions. Bifluoride source compounds that form bifluoride species in this manner are readily identified by those skilled in the art without undue experimentation. Examples of such compounds include ammonium fluoride, fluoroborates, fluoroboric acid, tin bifluoride, antimony fluoride, tetrabutylammonium tetrafluoroborate, aluminum hexafluoride, and the like. More than one carboxylic acid or bifluoride source compound may be employed. Hydrogen fluoride acid addition and quaternary salts of organic nitrogen-containing compounds are also bifluoride source compounds. These include acid addition and quaternary salts of aliphatic amines, aromatic amines and nitrogen-containing heterocyclic compounds. The amines include primary, secondary and tertiary amines.

For purposes of the present invention, bifluoride source compounds that form a bifluoride species when dissolved in a carboxylic acid are defined as excluding hydrofluoric acid, which forms such species in the absence of other acids, and which does not provide etching compositions with selectivity toward silicon oxides.

Ammonium fluoride is among the preferred bifluoride source compounds. Two moles of ammonium fluoride combine with one mole of a monocarboxylic acid, such as acetic acid, to form one mole of ammonium bifluoride and one mole of ammonium acetate (a carboxylic acid species), as shown below:

2NH₄F+CH₃COOH→(NH₄)⁺(HF₂)⁻+(CH₃COO⁻)(NH₄⁺)

This is shown to illustrate how bifluoride species are formed in a carboxylic acid solution, and is not meant in any way to limit the invention to combinations of NH₄F and acetic acid. However, this is among the particularly preferred embodiments of the present invention.

Silicon oxide etching rates increase as the bifluoride source compound concentration increases, without adversely affecting the selectivity for silicon oxides over metals. A total bifluoride source compound concentration between about 1.75 and about 3.75 moles per kilogram of solvent is preferred. Examples of etching compounds of the present invention containing ammonium fluoride and acetic acid include compounds containing from about 7% to about 14% by weight ammonium fluoride and from about 1.5 to about 5% by weight water with the balance of the composition being acetic acid.

The etchant compositions of the present invention are prepared by adding a stoichiometric quantity of one or more acid anhydrides to an aqueous solution of at least one bifluoride source compounds to form upon contact with water at least one of the carboxylic acids intended for use in the etching compositions. One or more of the carboxylic acids may be present in the aqueous bifluoride source compound solution, provided that enough acid anhydride is stoichiometrically employed to attain the desired reduction in water content.

For compositions containing more than one carboxylic acid, more than one acid anhydride may be used to dehydrate the aqueous bifluoride source compound solution, to form carboxylic acids intended for use in the etching composition upon contact with the water, even when the corresponding carboxylic acids are already present in the aqueous solution. Alternatively, one of the intended carboxylic acids may be added as an acid anhydride, while the other(s) are present as carboxylic acids in the aqueous solution.

For purposes of the present invention, compositions according to the present invention that “consist of” or “consist essentially of” a solution of at least one bifluoride source compound in one or more carboxylic acids are defined as including residual amounts of at least one corresponding acid anhydride resulting from the use of a stoichiometric excess to dehydrate the composition. A stoichiometric excess is employed when complete dehydration is desired.

Thus, for etching compositions containing acetic acid, acetic anhydride is used, and so forth. The concentration of the bifluoride source compound in the aqueous solution is selected to provide the desired concentration of bifluoride source compounds and water in the inventive composition upon reaction of the acid anhydride with the water to form the carboxylic acid solvent.

The reaction is exothermic, requiring the removal of, rather than the addition of, thermal energy. The reaction runs to completion within about six hours. The conditions and apparatus for preparing the compositions of the present invention by this method are essentially conventional and require no further description.

Alternatively, the compositions of the present invention prepared by reacting ammonium fluoride with acetic acid and/or acetic anhydride and water to form ammonium bifluoride and ammonium acetate can be prepared by the method disclosed in WO 00/58,208, the disclosure of which is incorporated herein by reference. For example, stoichiometric quantities of anhydrous gaseous or liquid hydrogen fluoride and anhydrous gaseous or liquid ammonia can be added to a stoichiometric amount of a carboxylic acid to obtain the mixture of ionic species that would otherwise form by reacting ammonium fluoride with a carboxylic acid, i.e., ammonium bifluoride and ammonium carboxylate. Employment of the proper stoichiometric quantities of hydrogen fluoride, ammonia gas and carboxylic acid in the processes described by this publication will result in the desired concentrations of ammonium bifluoride and ammonium carboxylate. Furthermore, the process permits the concentrations of ammonium fluoride, carboxylic acid and water, if present, to be prepared with pinpoint accuracy.

The methods of the present invention for selectively removing silicon oxides from metal surfaces are performed by employing the inventive compositions in conventional etching and cleaning processes that require no further description. The processes are typically carried out at temperatures between about 20 and about 50° C., and preferably from about 20 to about 30° C.

For example, a solution of ammonium fluoride in acetic acid is prepared by adding acetic anhydride to an aqueous solution of ammonium fluoride, preferably under controlled temperature conditions. In particular, the reaction temperature is preferably maintained below 40° C. to avoid the formation of acetamide as a by-product formed by a reaction that occurs between the ammonium moiety and the anhydride at higher temperatures. A temperature between about 10 and about 40° C. is preferred, with a temperature between about 20 and about 30° C. even more preferred.

The formation of acetamide is undesirable because it slows the etching rate and tends to fog silicon wafer surfaces. Reaction temperatures should be controlled for essentially any reaction between ammonium fluoride and an acid anhydride to prevent the formation of undesirable acid amides that in general slow the rate of etching.

The acid anhydride addition to the aqueous fluoride source should be slowly apportioned to allow the initial reaction between the water and the anhydride to occur before adding additional anhydride. This will maximize dehydration of the solution and, for reactions between ammonium fluoride and acid anhydrides, minimize acid amide formation by preventing excessive heat from being generated that would otherwise result in over-heating of the reaction mixture.

As noted above, the methods of the present invention may be used to selectively remove silicon oxides from essentially any metal surface. Thus, the inventive methods and compositions may be used to remove silicon oxides from semiconductor bonding pads, including silicon oxide coating layers that have been applied as passivation coatings, and silicon oxide deposits that have formed during semiconductor fabrication process steps, including the process steps of reactive ion etching. In addition, the compositions and methods may be used to remove silicon oxides to open semiconductor vias for subsequent metal deposition. The compositions of the present invention are ideally selective in the removal of silicon oxides from aluminum surfaces, and may thus be used not only to remove silicon oxides from aluminum bonding pads, but also to remove the silicon oxide deposits that form on the anodized aluminum parts of sputtering equipment and gaseous deposition equipment used for the reactive ion etching of semiconductor devices.

The methods of the present invention for selectively removing metal silicates from metal surfaces similarly employed the inventive compositions in conventional cleaning processes that require no further description. These processes are also typically carried out at essentially the same temperatures.

The metal silicates typically form on metal surfaces as a consequence of plasma etching processes. Typically, aluminum silicates or titanium silicates form on aluminum and titanium surfaces, respectively. The compositions of the present invention will remove the metal silicates without attacking the underlying metal. The compositions will also not attack any organic dielectric coating that may be formed on the metal surfaces.

The following non-limiting examples are presented to further illustrate the present invention.

### EXAMPLE

A 1.1 kilogram quantity of an etching composition according to the present invention was prepared by adding 850 g acetic anhydride to 250 g of a 40% by weight aqueous solution of ammonium fluoride. The ammonium fluoride solution was prepared by adding 100 g of ammonium fluoride to 150 g of water. The acetic anhydride was then added slowly.

Specifically, the ammonium fluoride solution was placed in a 500 mL polyethylene beaker in a ice bath and stirred slowly. The acetic anhydride was added to the ammonium fluoride solution from a 500 mL delivery buret in 30 to 40 mL increments to prevent the generation of excessive heat. The temperature of the reaction mixture was monitored, and within 45 minutes rose to about 30° C., signaling the start of the reaction. Mixing continued until the reaction mixture cooled to room temperature, at which point an additional 30 to 40 mL of acetic anhydride was added. The temperature of the reaction mixture rose again, and it was once again permitted to cool, with stirring, before more acetic anhydride was added. After 2 ½ hours the acetic anhydride addition was complete, after which the mixture was stirred for an additional hour. The resulting composition was essentially free of water and acetic anhydride and contained 9.1% by weight ammonium fluoride (i.e., 90.1% by weight acetic acid).

The etching composition was contacted with the aluminum bonding pads of a semiconductor device that were coated with silicon oxides as a passivation layer. The device included exposed aluminum surfaces. The etching solution was contacted until the silicon oxides were completely removed from the bonding pad. There was no detectable removal of aluminum from the bonding pads or the exposed aluminum surfaces.

In this disclosure, there are shown and described only the preferred embodiments of the invention. It is to be understood that the invention is capable of use in various other combinations and environments and is capable of changes or modifications within the scope of the inventive concept as expressed herein.

What is claimed is:

1. A silicon oxide etching solution consisting essentially of the product of at least one bifluoride source compound dissolved in a solvent consisting of about 90% to 100% by weight of one or more carboxylic acids and 0 to about 10% by weight of water, wherein the total bifluoride source compound concentration is between about 1.25 and about 5.0 moles per kilogram of solvent.

2. The solution of claim 1, comprising the product of a monocarboxylic acid having from 0 to five carbon atoms in addition to the carboxylate carbon.

3. The solution of claim 2, wherein said monocarboxylic acid is acetic acid.

4. The solution of claim 1, wherein at least one bifluoride source compound is selected from the group consisting of ammonium fluoride, fluoroborates, fluoroboric acid, tin bifluoride, antimony fluoride, tetrabutylammonium tetrafluoroborate, aluminum hexafluoride, hydrogen fluoride acid addition and quaternary salts of organic nitrogen-containing compounds and mixtures thereof.

5. The solution of claim 4, wherein a bifluoride source compound is ammonium fluoride.

6. The solution of claim 5, consisting of the product of from about 7% to about 14% by weight ammonium fluoride, from about 1.5% to about 5% by weight water and acetic acid.

7. The solution of claim 4, wherein said organic nitrogen-containing compounds are selected from the group consisting of aliphatic amines, aromatic amines and nitrogen-containing heterocycles.

8. A method for selectively removing silicon oxides from metal surfaces comprising contacting a metal surface having silicon oxides thereon with the etching solution of claim 1 for a period of time effective to remove at least a portion of said silicon oxides.

9. The method of claim 8, wherein said contacting step is performed on said surface until essentially all of said silicon oxides have been removed.

10. The method of claim 8, wherein said metal surface comprises one or more metals selected from the group consisting of aluminum, copper, tungsten, tin, titanium, nickel, vanadium and lead.

11. The method of claim 10, wherein said metal surface consists essentially of aluminum.

12. The method of claim 8, wherein said silicon oxides are removed from a semiconductor bonding pad surface.

13. The method of claim 12, wherein said bonding pad surface consists essentially of aluminum.

14. The method of claim 13, wherein said silicon oxides were applied to said bonding pad surface as a passivation coating.

15. The method of claim 8, wherein said silicon oxides are removed from a metal surface to open a via in a semiconductor device.

16. The method of claim 8, wherein said silicon oxides are removed from the metal parts of equipment used for the reactive ion etching of semiconductor devices.

17. The method of claim 16, wherein said metal parts have anodized aluminum surfaces.

18. The method of claim 16, wherein said metal parts are used in sputtering equipment or gaseous deposition equipment.

19. The method of claim 8 wherein said etching solution consists essentially of the product of a bifluoride source compound and a monocarboxylic acid.

20. A method for the preparation of an ammonium bifluoride etching solution that is essentially free of acid amides, said method comprising the step of reacting an aqueous solution of ammonium fluoride with an acid anhydride at a temperature below that at which carboxylic acid amide formation occurs.

21. The method of claim 20, wherein said temperature is below about 40° C.

22. The method of claim 21, wherein said temperture is between about 20 and about 30° C.

23. The method of claim 20, wherein said acid anhydride is acetic anhydride.

24. A method for selectively removing metal silicates from metal surfaces comprising contacting a metal surface having a silicate of said metal formed thereon with the etching solution of claim 1 for a period of time effective to remove at least a portion of the metal silicate.

25. The method of claim 24, wherein said metal is titanium or aluminum.

26. The method of claim 24, wherein said metal surface is at least partially coated with at least one organic dielectric.

27. The method of claim 24, wherein said contacting step is performed until essentially all of said metal silicate has been removed.
